(19) United States
(12) Patent Application Publication
(10) Pub. No.: US 2007/0242838 A1
(43) Pub. Date: Oct. 18, 2007

(54) Electronic Device and Sound Level Control Method

(75) Inventor: Masafumi Ichinose, Tochigi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Sony Corporation, Minato-ku (JP)

(21) Appl. No.: 11/573,559

(22) PCT Filed: Aug. 22, 2005
(86) PCT No.: PCT/JP05/15587

§ 371 Date: Feb. 12, 2007

(30) Foreign Application Priority Data
Aug. 30, 2004 (JP) 2004-250616

(51) Int. Cl. H03G 3/20

(52) U.S. Cl. 381/107

(57) ABSTRACT

To enable to control an audio sound to a suitable volume level corresponding to the using condition of electronic equipment.

In a portable disk device 2 that can be attached to a cradle 3, a connection detecting line DET connected to a control part 50 for detecting an attached state or an unattached state to the cradle and a pullup resistance 56, the control part 50 for controlling to set, if it is detected that the portable disk device 2 is in the unattached state, an audio sound to be emitted from the above portable disk device 2 to dedicated headphones 15 to a volume level based on a predetermined headphone volume value VH, and to switch, if being in the attached state is detected, an audio sound to be emitted from speakers 4L and 4R via the above cradle 3 from the volume level based on the headphone volume value VH to a volume level based on a line volume value VL larger than the above headphone volume value VH, and a DSP 53 are provided.

### TECHNICAL FIELD

The present invention relates to electronic equipment and a method for controlling a volume level, and is suitably applicable to a portable disk device for recording or reproducing music by using a magneto-optical disk such as MINI DISC (registered trademark), for example.

### BACKGROUND ART

Heretofore, a portable disk device is formed in a small size and a light weight so that a user can readily carry. The disk device reads and reproduces a music composition from a disk cartridge of MINI DISC (registered trademark), adjusts an audio sound to a volume level of the user's preference, and makes the user listen to the music composition via headphones.

Some of this type of portable disk devices are formed to be able to be attached to a dedicated cradle. It has been proposed that the disk device is electrically connected to the cradle by only attached to the above cradle, and the sound of the reproduced music composition can be emitted from a speaker built in the cradle (see Patent Document 1, for example.)

Further, in a portable disk device having the above configuration, when it was attached to the cradle, the volume level of the sound to be emitted from the speaker is adjusted by making the user operate a volume adjusting button on the portable disk device, similarly to the use of the headphones.

Patent Document 1—Japanese Patent Laid-Open No. Hei5-153035 (P. 3, FIG. 1).

By the way, in general, an audio signal at a relatively small volume level is supplied to headphones having a relatively small oscillator, and an audio signal at a relatively large volume level is supplied to a speaker having a relatively large oscillator. Thereby, sounds at a suitable volume level can be emitted respectively.

Accordingly, when the portable disk device is attached to a cradle, it is necessary that a volume level is relatively large so that an audio sound at a suitable volume level is emitted from the speaker of the above cradle. On the other hand, when the portable disk device is not attached to the above cradle, it is necessary that a volume level is relatively small so that an audio sound at a suitable volume level is emitted from headphones.

Therefore, in the portable disk device, it is necessary that a volume level is adjusted by a user every time when the disk device is attached to the cradle, and every time when it is detached from the above cradle. There has been a problem that the user is forced to perform a complicated operation every time.

### DISCLOSURE OF INVENTION

Considering the above point, the present invention provides electronic equipment and a method for controlling a volume level that can control an audio sound to a suitable volume level corresponding to the using condition of the electronic equipment

To obviate such problem, according to electronic equipment of this invention, it is electronic equipment that can be attached to a cradle, and detecting means for detecting an attached state or an unattached state to the cradle, and control means for controlling to set, if it is detected that the electronic equipment is in the unattached state to the cradle, an audio sound to be emitted from the above electronic equipment to a predetermined first volume level and to switch, if it is detected that the electronic equipment is in the attached state to the cradle, an audio sound to be emitted from the cradle from the first volume level to a predetermined second volume level larger than the above first volume level are provided.

Thereby, when the electronic equipment is in the attached state, an audio sound at a first volume level is emitted from the above electronic equipment and when the above electronic equipment made the transition from the unattached state to the attached state, the sound is automatically switched from the first volume level to the second volume level. And when the above electronic equipment made the transition from the attached state to the unattached state, the sound can be automatically switched from the second volume level to the first volume level.

According to a method for controlling a volume level of this invention, it is a method for controlling a volume level of electronic equipment that can be attached to a cradle, the detection step of detecting an attached state or an unattached state to the cradles and the control step of controlling to set, if it is detected that the electronic equipment is in the unattached state to the cradle, an audio sound to be emitted from the above electronic equipment to a predetermined first volume level, and to switch, if it is detected that it is in the attached state to the cradle, an audio sound to be emitted from the cradle from the first volume level to a predetermined second volume level larger than the above first volume level are provided.

Thereby, when the electronic equipment is in the attached state, an audio sound at a first volume level is emitted from the above electronic equipment, and when the above electronic equipment made the transition from the unattached state to the attached state, the sound is automatically switched from the first volume level to the second volume level. And when the above electronic equipment made the transition from the attached state to the unattached state, the sound can be automatically switched from the second volume level to the first volume level.

Further, according to an electronic equipment system of this invention, it is an electronic equipment system having electronic equipment and a cradle to which the above electronic equipment can be attached. The above electronic equipment provides detecting means for detecting an attached state or an unattached state to the cradle, and control means for controlling to set, if it is detected that the electronic equipment is in the unattached state to the cradle, an audio sound to be emitted from the above electronic equipment to a predetermined first volume level, and to switch, if it is detected that the electronic equipment is in the attached state to the cradle, an audio sound to be emitted from the cradle from the first volume level to a predetermined second volume level larger than the above first volume level.

Thereby, when the electronic equipment is in the attached state, an audio sound at a first volume level is emitted from the above electronic equipment, and when the above electronic equipment made the transition from the unattached state to the attached state, the sound is automatically switched from the first volume level to the second volume level. And when the above electronic equipment made the transition from the attached state to the unattached state, the sound can be automatically switched from the second volume level to the first volume level.

According to the present invention, when the electronic equipment is in the attached state, an audio sound at a first volume level is emitted from the above electronic equipment, and when the above electronic equipment made the transition from the unattached state to the attached state the sound is automatically switched from the first volume level to the second volume level. And when the above electronic equipment made the transition from the attached state to the unattached state, the sound can be automatically switched from the second volume level to the first volume level. Therefore, electronic equipment and volume level control means that can control an audio sound to a suitable volume level corresponding to the using condition of the electronic equipment can be realized.

### BRIEF DESCRIPTION OF DRAWINGS

FIG. 1 is a schematic perspective view showing an overall configuration of a portable disk device system of the present invention.

FIG. 2 is a schematic perspective view showing the configuration of a portable disk device.

FIG. 3 is a schematic perspective view showing the configuration of a cradle.

FIG. 4 is a block diagram showing the circuit configuration of the portable disk device system.

FIG. 5 is a flowchart showing an output level switching processing procedure.

### BEST MODE FOR CARRYING OUT THE INVENTION

An embodiment of the present invention will be described in detail with reference to the accompanying drawings.

(1) Configuration of Portable Disk Device System

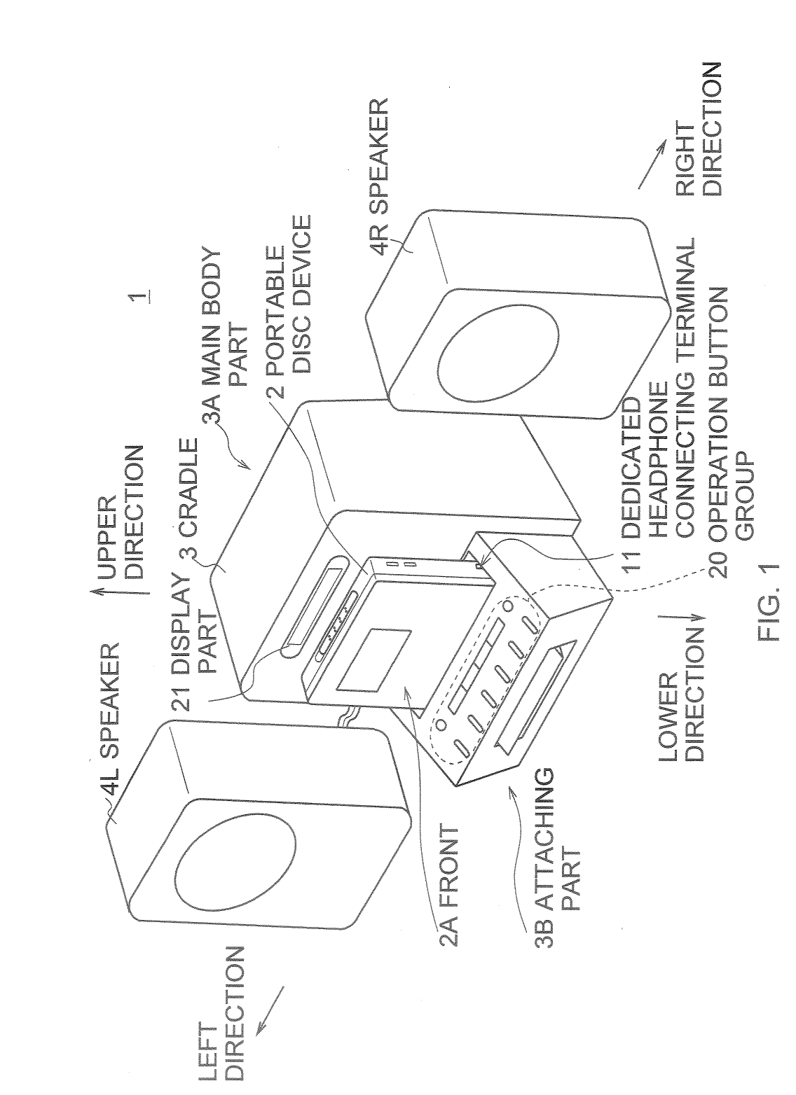

Referring to FIG. 1, the reference numeral 1 designates an overall configuration of a portable disk device system according to the present invention. A portable disk device 2 cope with MINI DISC (registered trademark) can be attached to a cradle 3.

By that a disk cartridge (not shown) of MINI DISC (registered trademark) is loaded, the portable disk device 2 can reproduce a music composition recorded in the above disk cartridge, and also can newly record a music composition to the above disk cartridge in a Net MD (registered trademark, the detail will be described later) format. Moreover, the portable disk device 2 is formed in a small size and a light weight so as to be readily carried by a user.

In the cradle 3, the portable disk device 2 can be attached to an attaching part 3B projected from a main body part 3A. If the portable disk device 2 is attached, a charging battery built in the above portable disk device 2 can be charged. In addition to this, a music composition is reproduced by the portable disk device 2, and the sound can be emitted via speakers 4L and 4R, corresponding to an operation via an operation button group 20 provided on the above attaching part 3B (the detail will be described later.)

Note that, in the portable disk device system 1, a left direction and a right direction are defined when a user faces to the cradle 3 to operate the operation button group 20 on the cradle 3 and also faces to the front 2A of the portable disk device 2. Further, the direction in that the portable disk device 2 is attached to the above cradle 3 is defined as a lower direction, and the direction in that the portable disk device 2 is detached from the above cradle 3 is defined as an upper direction. Under these definitions, a description will be given below.

(1-1) Configuration of Portable Disk Device

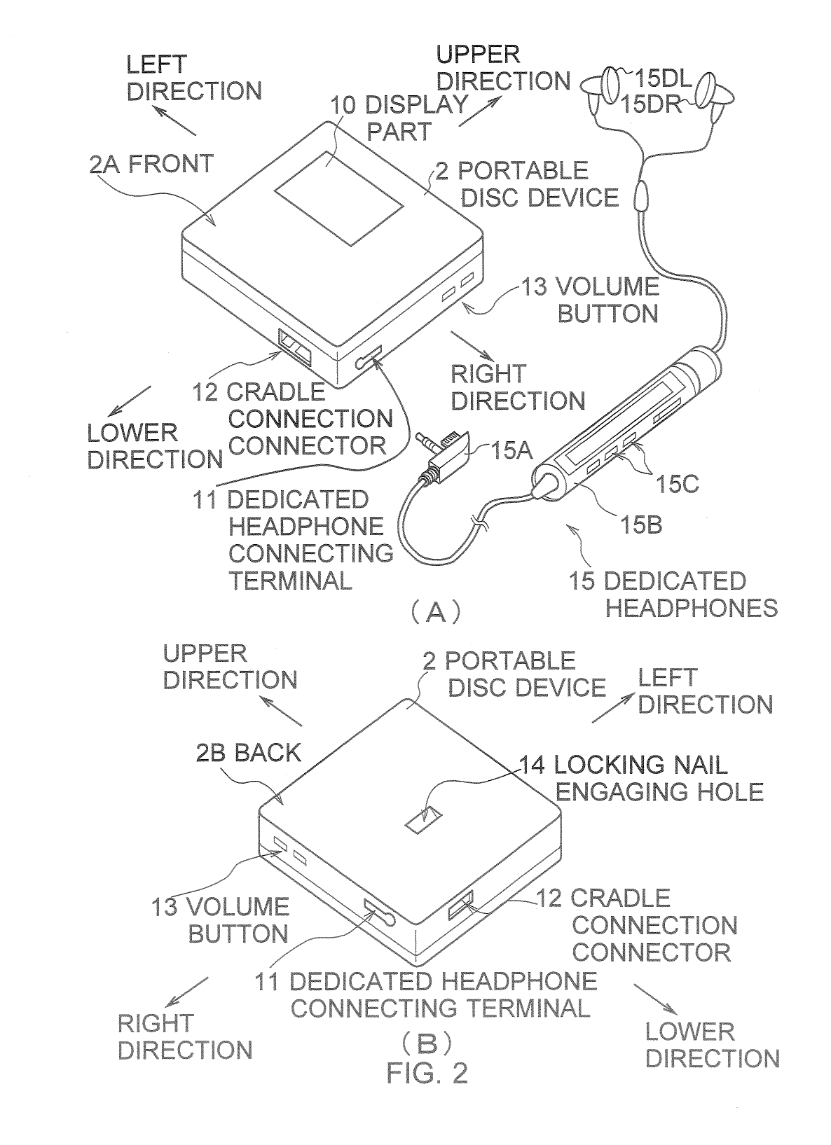

As shown in FIG. 2A, in the portable disk device 2, a display part 10 being a liquid crystal display for displaying an operating state, reproducing time or the like is provided on the front 2A, and a cradle connection connector 12 for electrically connecting, if the portable disk device system 1 is attached to the cradle 3, the portable disk device 2 to the above cradle 3 is provided on the lower side surface.

Further, in the portable disk device 2, a dedicated headphone connecting terminal 11 for connecting dedicated headphones 15 that has a remote controller (hereinafter, this is referred to as a “rimocon”: the word meaning a remote controller that is generally used in Japan) function is provided at the lower part of the right side surface. Further, a volume button 13 to make a user adjust a volume level is provided at the upper part of the right side surface.

If the connector 15A of the dedicated headphones 15 is connected to the dedicated headphone connecting terminal 11, the portable disk device 2 performs reproducing of a music composition or the like according to the operation of an operation button 15C provided on a remote controller part 153, and makes the user listen to the sound via output parts 15DL and 15DR.

Note that, as shown in FIG. 1, in the portable disk device 2, the dedicated headphone connecting terminal 11 is intentionally provided at a position that is closed by the attaching part 33 when the portable disk device 2 has been attached to the attaching part 3B of the cradle 3. Therefore, the portable disk device 2 cannot be attached to the cradle 3 without detaching the dedicated headphones 15.

Further, as shown in FIG. 23, in the portable disk device 2, a locking nail engaging hole 14 is provided at the almost center part of a back 2B. Thus, when the portable disk device 2 is attached to the cradle 3, the portable disk device 2 is locked into the cradle 3 by the above locking nail engaging hole 14 so as to prevent the portable disk device 2 from being excessively detached from the cradle 3 (the detail will be described later.)

(1-2 Configuration of Cradle

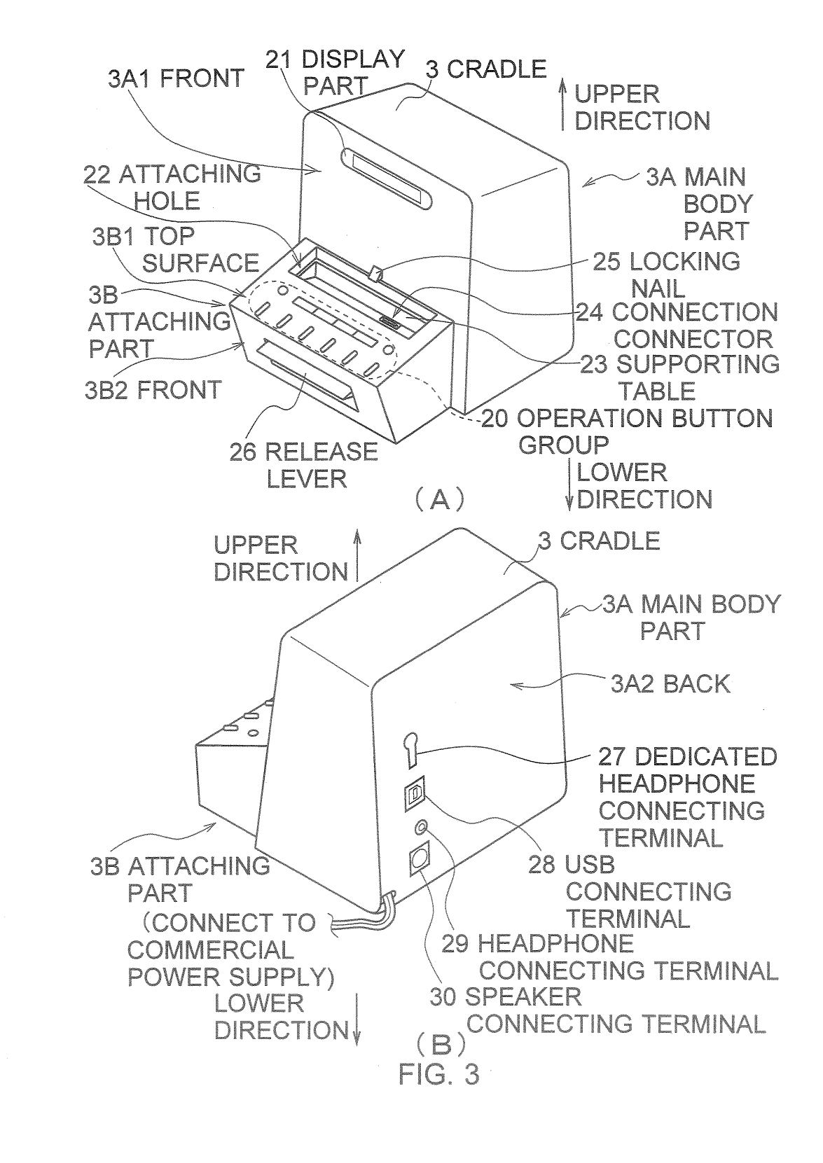

As shown in FIG. 3A, in the cradle 3, the attaching part 3B in an almost rectangular parallelopiped shape that projects to the front 3A1 side of the main body part 3A in an almost rectangular parallelopiped shape is provided. A display part 21 being a liquid crystal display is provided at the upper part of the front 3A1 of the main body part 3A, and an operating mode or the like that will be described later is displayed in it.

On the attaching part 3B of the cradle 3, the operation button group 20 is provided on this side of the top surface 3B1, and an attaching hole 22 for attaching a portable disk device 2 is provided on the back side of the above top surface 3B1. Inside the above attaching hole 22, a supporting table 23 for supporting the portable disk device 2 is provided so as to be movable upward and downward in the above attaching hole 22. in the state where the portable disk device 2 is not attached, the above supporting table 23 is pressed up upward by the pressing power of a built-in spring.

Inside the attaching hole 22, a connection connector 24 is provided at a position corresponding to the cradle connection connector 12 of the portable disk device 2 (FIG. 2A). In the cradle 3, if a portable disk device 2 is inserted, the supporting table 23 is pressed down, the portable disk device 2 is attached, and the cradle connection connector 12 is connected to the above connection connector 24. Thereby, the cradle 3 is electrically connected to the above portable disk device 20.

Furthermore, in the main body part 3A of the cradle 3, a locking nail 25 that has been pressed in a state projecting by the pressing power of a built-in spring is provided at the almost center of the front 3A1.

In the cradle 3, at the time when the portable disk device 2 is inserted into the attaching hole 22, when the locking nail 25 is temporarily pressed down by the back 2B of the portable disk device 2, and the above portable disk device 2 is inserted to an attaching position, the locking nail 25 is engaged with the locking nail engaging hole 14 of the above portable disk device 2 (FIG. 2B). It stops the portable disk device 2 moving upward, that is, the attached state of the portable disk device 2 to the cradle 3 is kept.

Furthermore, on the front 3B2 of the attaching part 3B, a release lever 26 for detaching the portable disk device 2 attached to the cradle 3 is provided. In the cradle 3, if the release lever 26 is pushed downward by a user, the locking nail 25 is first temporarily drawn down inside the front. Thereby, the cradle 3 is released from the state engaged with the locking nail engaging hole 14 of the portable disk device 2 (FIG. 2B).

Next, in the cradle 3, the supporting table 23 is pressed upward to lift the portable disk device 2, so that the connection connector 24 is electrically disconnected from the cradle connection connector 12. Thereby, the above portable disk device 2 is separated from the cradle 3, and makes the transition from the attached state to an unattached state.

Furthermore, as shown in FIG. 3B on the back 3A2 of the main body part 3A of the cradle 3, a dedicated headphone connecting terminal 27 for connecting dedicated headphones 15 (FIG. 2A), a USB connecting terminal 28 for connecting the cradle 3 to a personal computer (not shown) by a USB (Universal Serial Bus) cable (not shown), a headphone connecting terminal 29 for connecting external headphones (not shown), and a speaker connecting terminal 30 for connecting speakers 4L and 4R are provided.

In this connection, in the cradle 3, in the case where external headphones (not shown) are connected to the headphone connecting terminal 29, an audio sound is emitted from the above headphones without emitted from the speakers 4L and 4R.

(2) Circuit Configuration of Portable Disk Device

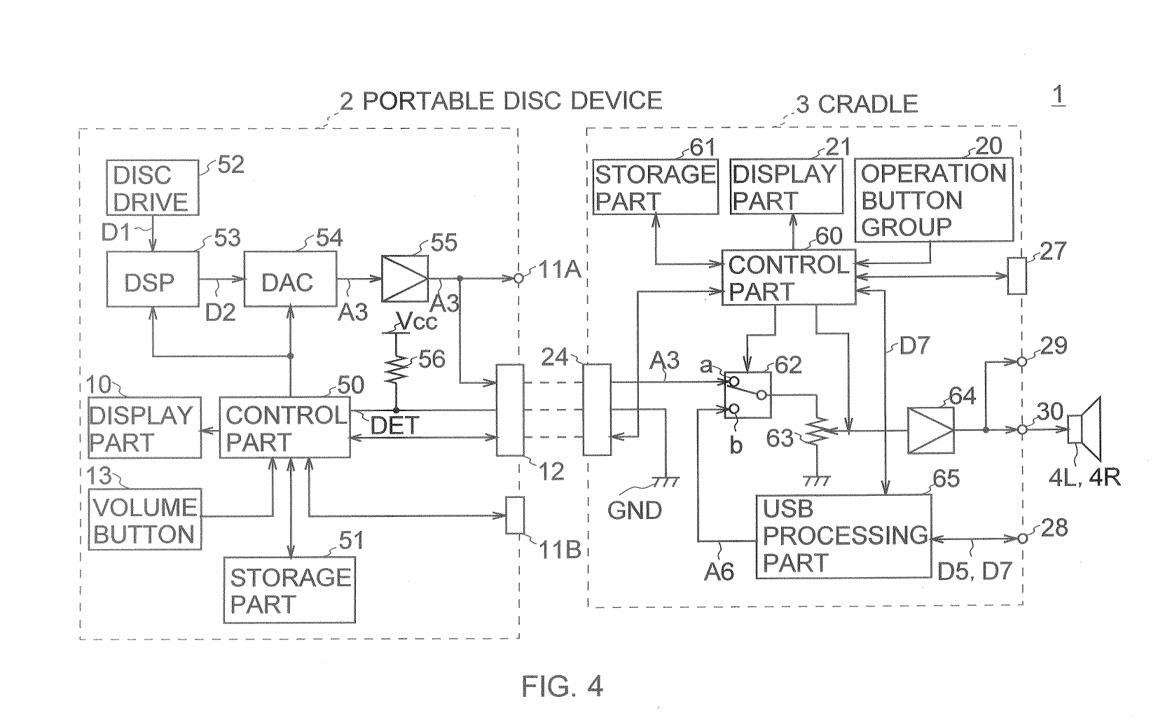

Next, the circuit configuration of the portable disk device 2 will be described. As shown in FIG. 4, in the portable disk device 2, the whole of it is integrally controlled by a control part 50 being a CPU (Central Processing Unit) configuration.

The control part 50 always monitors the potential of a connection detecting line DET, and determines whether or not the potential of the connection detecting line DET is a predetermined threshold value TH or above (however, 0<threshold value TH<power supply Vcc), that is, the potential is a high “H” level or a low “L” level.

This connection detecting line DET is connected to the power supply Vcc via a pullup resistance 56, and is further connected to the cradle connection connector 12. However, in the case where the portable disk device 2 is not attached to the cradle 3, the connection detecting line DET is not connected to the connection connector 24 of the cradle 3 on the cradle connection connector 12 side and is opened, so that the potential is almost same as the power supply Vcc.

Therefore, the control part 50 determines that the potential of the connection detecting line DET is “H” level higher than the threshold value TH. Thereby, the control part 50 detects that the cradle connection connector 12 is not connected to the connection connector 24 of the cradle 3, that is, that the portable disk device 2 is in an “unattached state” not attached to the cradle 3 is detected.

In the control part 50, it is presumed that the dedicated headphone 15 !FIG. 2A) will be connected to the dedicated headphone connecting terminal 11 in this unattached state. Operation instructions such as reproducing of a music composition, and control of volume level by the operation button 15C of the dedicated headphone 15 are accepted, via a remote control terminal part 11B of the above dedicated headphone connecting terminal 11, and an operation instruction such as control of volume level by the volume button 13 is accepted.

By the control part 50, head-hone volume values VH as a first volume level that means a volume level when an audio sound is emitted from the dedicated headphone 15 and a user volume level are stored in a storage part 51 being a nonvolatile memory. If an operating instruction to adjust a volume level is accepted via the operation button 15C, the volume button 13, or the like of the dedicated headphone 15, the above headphone volume value VH is changed according to the above operating instruction, and the headphone volume value VH after the change is kept.

Further, if an instruction to reproduce a music composition by the user is accepted via the operation button 15C of the dedicated headphone 15, the control part 50 controls a disk drive 52 to read music data D1 from a disk cartridge (not shown) loaded in the above disk drive 52, and transmits this to a DSP (Digital Signal Processor) 53.

The DSP 53 performs predetermined decoding processing or the like on the music data D1 to decode this into digital audio data D2. Further, by the control of the control part 50, the audio data D2 is adjusted to a volume level based on the headphone volume value VH stored in the storage part 51. The adjusted data is transmitted to a DAC (Digital Analog Converter) 54.

The DAC 54 converts the digital audio data D2 into an analog audio signal A3, and transmits this to an amplifier 55. The amplifier 55 amplifies the analog audio signal A3 at a constant amplification factor so as to adjust the voltage of the above analog audio signal A3 to approximately 400 mV degree at maximum, that is, a headphone output level, and transmits this to a headphone terminal part 11A of the dedicated headphone connecting terminal 11.

Thereby, in this unattached state, the portable disk device 2 can make the user listen to an audio sound corresponding to the headphone volume value VH, that is, adjusted to the user's preference, via output parts 15DL and 15DR of the dedicated headphones 15 (FIG. 2A) that have been connected to the dedicated headphone connecting terminal 11.

By the way, if the portable disk device 2 is attached to the cradle 3 by the user, the cradle connection connector 12 is connected to the connection connector 24 of the cradle 3. At this time, the connection detecting line DET is grounded via the cradle connection connector 12 and the connection connector 24. Thus, the potential is almost 0 V.

According to this, the control part 50 determines that the potential of the connection detecting tine DET is “L” level lower than the threshold value TH (0<threshold value TH<power supply Vcc). As a result, it is detected that the cradle connection connector 12 has been connected to the connection connector 24 of the cradle 3, that is, the portable disk device 2 is in an “attached state” attached to the cradle 3.

In this attached state, the control part 50 controls the DSP 53 to switch the digital audio data D2 to a volume level based on a predetermined line volume value VL. In this connection, the line volume value VL is a fixed value that means a volume level when in outputting the analog audio signal A3 to the cradle 3, and shows a volume level larger than the maximum value of a changeable headphone volume value VH.

As a result, in the portable disk device 2, the voltage of the analog audio signal A3 to be outputted via the DAC 54 and the amplifier 55 is adjusted to a so-called line output level of approximately 1 V degree, and the above analog audio signal A3 is transmitted to the cradle 3 via the cradle connection connector 12 and the connection connector 24.

In this connection, in the portable disk device 2 in the aforementioned attached state, since the dedicated headphone connecting terminal 11 is closed with the cradle 3, the dedicated headphone 15 is not connected thereto. It is considered that erroneously transmitting the analog audio signal A3 at the line output level from the headphone terminal part 1A of the dedicated headphone connecting terminal 11 to the output parts 15DL and 15DR of the dedicated headphones 15 (FIG. 2A) is limited.

Furthermore, in the portable disk device 2 in this attached state, an input operation by the volume button 13 is ineffective. Thereby, it is prevented that the user chances the headphone volume value VH by mistake.

(3) Circuit Configuration of Cradle

As shown in FIG. 4, the whole of the cradle 3 is integrally controlled by a control part 60 having a CPU configuration. By the control part 60, a speaker volume value VS as a second volume level that means a volume level of an audio sound emitted from the speakers 4L and 4R is stored in a storage part 61 being a nonvolatile memory. If a volume adjust button provided in the operation button group 20 is operated the above speaker volume value VS is changed according to the operating instruction, and the above speaker volume value VS after the change is kept in the storage part 61.

Further, the cradle 3 has three operation modes: “MD mode” in that an audio sound reproduced by the portable disk device 2 is emitted from the speakers 4L and 4R, “USS speaker mode” in that the cradle 3 operates as an external speaker of a personal computer (not shown), and “Net MD (registered trademark) mode” in that music data transmitted from a personal computer is recorded to a disk cartridge loaded in the portable disk device 2. Each operation mode is switched by the user via the operation button group 20.

(3-1) MD Mode

If the cradle 3 is switched to the “MD mode” via the operation button group 20, by the control part 60, “MD” is first displayed in the display part 21 so as to make the user recognize that the cradle 3 operates in the “MD” mode.

In the control part 60, it is presumed that in this “MD mode”, the portable disk device 2 has been attached to the cradle 3. If a “reproducing” button for operating the portable disk device 2 or the like provided in the operation button group 20 of the cradle 3 is operated, a signal corresponding to the operating instruction is transmitted to the portable disk device 2 via the connection connector 24. Thereby, the above portable disk device 2 performs reproducing of a music composition or the like.

At this time, the portable disk device 2 detects that it is in an attached state attached to the cradle 3, based on the potential of the connection detecting line DET, and transmits an analog audio signal A3 at a line output level to the cradle 3 via the cradle connection connector 12.

The control part 60 switches a switch 62 to the a side, so that the analog audio signal A3 obtained from the portable disk device 2 is supplied to a variable resistance 63 via the connection connector 24.

Further, the control part 60 controls the variable resistance 63 based on the speaker volume value VS stored in the storage part 61 and adjusts the analog audio signal A3 to a volume level based on the above speaker volume value VS, and transmits this to an amplifier 64. The amplifier 64 amplifies the analog audio signal A3 at a constant amplification factor, and transmits this to the speakers 4L and 4R via the speaker connecting terminal 30. Thereby, an audio sound at a volume level corresponding to the speaker volume value VS is emitted from the above speakers 4L and 4R.

In this manner, in the “MD mode”, the control part 60 of the cradle 3 obtains an analog audio signal A3 at a line output level from the portable disk device 2, so that an audio sound at a volume level corresponding to the speaker volume value VS is emitted from the speakers 4L and 4R.

Note that, if the dedicated headphones 15 (FIG. 2A) is connected to the dedicated headphone connecting terminal 27 (FIG. 3B), although the control part 60 accepts an operation by the operation button 15C of the above dedicated headphones 15, an audio sound is not emitted from the output parts 15DL and 15DR, and only the above operation button 15C is worked.

Further, if an external headphones (not shown) is connected to the headphone connecting terminal 29 (FIG. 33), by the control part 60, an audio sound is emitted from the above headphones not from the speakers 4L and 4R.

(3-2) USB Speaker Mode

If the cradle 3 is switched to the “USB speaker mode” via the operation button group 20, by the control part 60, “USP SP” is first displayed in the display part 21 so as to make the user recognize that the cradle 3 is operated in the “USB speaker mode”.

It is presumed that in this “USB speaker mode”, the cradle 3 will be connected to a personal computer (not shown) by a USB cable (not shown) via the USB connecting terminal 28. A digital audio signal DS transmitted from the above personal computer is obtained via the above USB cable.

By the control part 60 of the cradle 3, the digital audio data DS obtained from the personal computer via the USB connecting terminal 28 is converted into an analog audio signal A6 at a line output level by a USB processing part 65, and this is supplied to the switch 62.

Further, the control part 60 switches the switch 62 to the b side, so that the analog audio signal A6 is supplied to the variable resistance 63, and the control part 60 controls the variable resistance 63 based on the speaker volume value VS stored in the storage part 61, similarly to the aforementioned “MD mode”. Thereby, the analog audio signal A6 is adjusted to a volume level based on the above speaker volume value VS, and this is transmitted to the amplifier 64.

The amplifier 64 amplifies the analog audio signal A6 at a constant amplification factor, and transmits this to the speakers 4L and 4R via the speaker connecting terminal 30. Thereby, an audio sound at a volume level corresponding to the speaker volume value VS is emitted from the above speakers 4L and 4R.

In this manner, in the USB speaker mode, the cradle 3 operates as an external speaker of a personal computer by the combination with the speakers 4L and 4R.

(3-3) Net MD (Registered Trademark) Mode

If the cradle 3 is switched to the “Net MD (registered trademark) mode” via the operation button group 20, by the control part 60, “Net MD” is first displayed in the display part 21 so as to make the user recognize that the cradle 3 operates in the “Net MD (registered trademark) mode”.

Also in this “Net MD (registered trademark) mode” similarly to the “USB speaker mode”, it is presumed that the cradle 3 will be connected to a personal computer (not shown) by a USB cable (not shown) via the USE connecting terminal 28.

In this personal computer, a predetermined Net MD (registered trademark) program is executed. According to the user's operation, music data stored in a storage medium of the above personal computer (for example, a hard disk drive or the like) is converted into music data D7 in a format corresponding to the Net MD (registered trademark), and the above music data D7 is transmitted to the cradle 3 via the USB cable.

If the music data D7 transmitted from the personal computer is obtained via the USB connecting terminal 28 and the USB processing part 65, the control part 60 of the cradle 3 transmits the above music data D7 to the portable disk device 2 via the connection connector 24.

Responding to this, the portable disk device 2 records the above music data D7 to a loaded disk cartridge.

(4) Output Level Switching Processing of Portable Disk Device

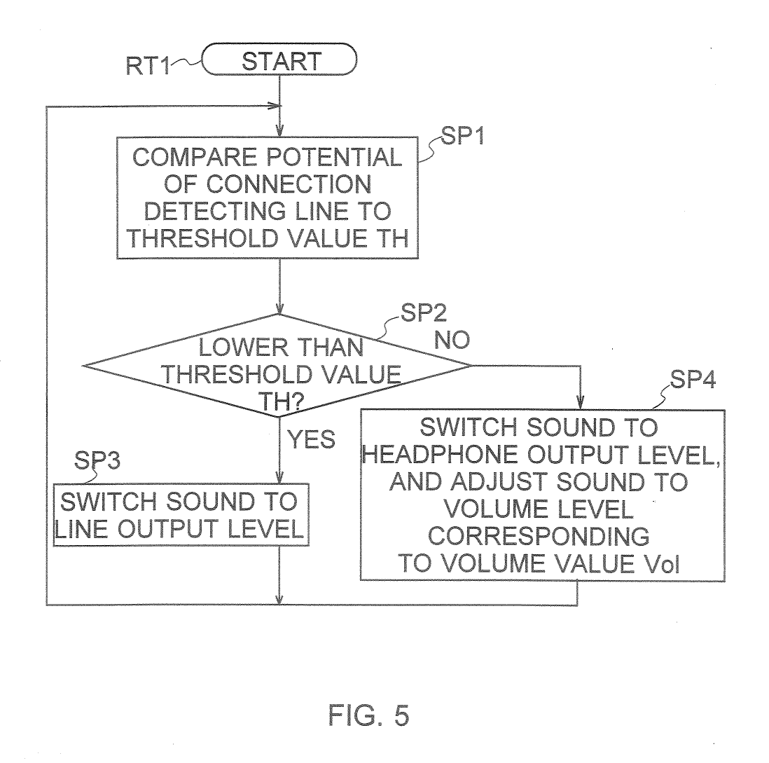

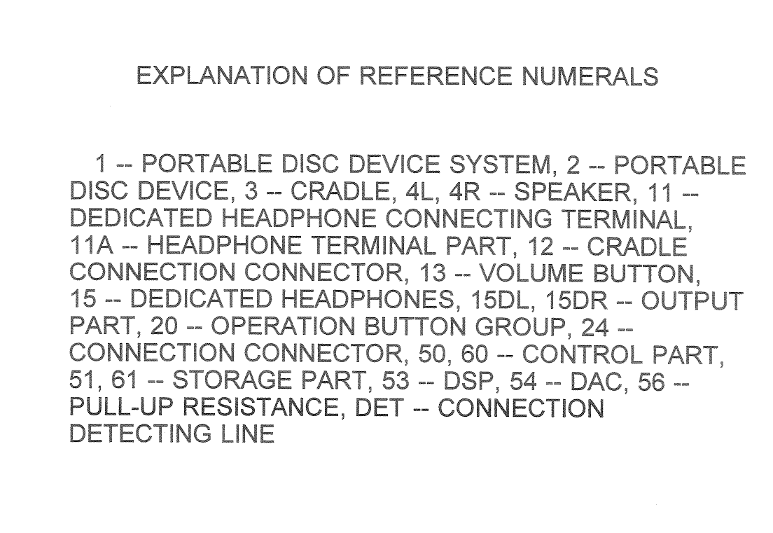

By the way, in the portable disk device 2, as described above, the output level of an analog audio signal A3 is switched depending on being an attached state or an unattached state to the cradle 3. An output level switching processing procedure at this time will be described with accompanying a flowchart of FIG. 5.

If the switch is turned on, the control part 50 of the portable disk device 2 starts the output level switching processing procedure RT1, and proceeds to step SP1. At step SP1, the control part 50 compares the potential of a connection detecting line DET (FIG. 4) to a threshold value TH, and proceeds to the next step SP2.

At step SP2, the control part 50 determines whether or not the potential of the connection detecting line DET is lower than the threshold value TH, that is, whether or not the potential of the above connection detecting line DET is “L” level. Here, if an affirmative result is obtained, the control part 50 detects that the portable disk device 2 is in an attached state and proceeds to the next step SP3 to emit an audio sound at a suitable volume level from the speakers 4 connected to the cradle 3.

At step SP3, the control part 50 makes the DSP 53 (FIG. 4) switch digital audio data D2 to a volume level based on a line volume value VL. Thereby, the volume level of the analog audio signal A3 to be outputted via the DAC 54 and the amplifier 55 is adjusted to a line output level, and the above analog audio signal A3 is transmitted to the cradle 3 via the cradle connection connector 1-2.

Responding to this, the cradle 3 adjusts the analog audio signal A3 at the line output level to a volume level corresponding to the speaker volume value VS. Thereby, an audio sound at a suitable volume level matching the user's preference is emitted from the speakers 4L and 4R (FIG. 4).

Then, the control part 50 returns to step SP1 again, and repeats a series of processing until the Dower supply of the portable disk device 2 is cut off.

On the other hand, if a negative result is obtained at step S2, this means that the potential of the connection detecting line DFT is “H” level. At this time, the control part 50 detects that the portable disk device 2 is in an unattached state, and proceeds to the next step SP4 to emit an audio sound at a suitable volume level from the output parts 15DL and L5DR of the dedicated headphones 15 (FIG. 2A).

At step SP4, the control part 50 makes the DSP 53 (FIG. 4) switch the volume level of the digital audio data D2 to a volume level based on the headphone volume value VH stored in the storage part 51. Thereby, the volume level of the analog audio signal A3 to be transmitted via the DAC 54 and the amplifier 55 is adjusted to a headphone output level, and the above analog audio signal A3 is transmitted to the headphone terminal part 11A of the dedicated headphone connecting terminal 11.

Thereby, in this unattached state, the portable disk device 2 can make the user listen to an audio sound at a volume level matching the user's preference, corresponding to the headphone volume value VH, that is, by the operation of the operation button 151 of the dedicated headphones 15 (FIG. 2A) or the volume button 13, via the output parts 15DL and 15DR of the dedicated headphones 15 (FIG. 2A) connected to the dedicated headphone connecting terminal 11.

And then the control part 50 returns to step SP1 again, and repeats a series of processing until the power supply of the portable disk device 2 is cut off.

(5) Operation and Effect

According to the above configuration, if the portable disk device 2 is attached to the cradle 3 by a user (FIG. 1), the portable disk device 2 determines that the potential of a connection detecting line DET (FIG. 4) is “L” level and detects that the above portable disk device 2 is in an attached state, makes the DSP 53 switch the volume level of digital audio data D2 from a volume level based on a headphone volume value VH to a volume level based on a line volume value VL, and transmits an analog audio signal A3 adjusted to a line output level to the cradle 3 via the cradle connection connector 12.

Therefore, only by that the portable disk device 2 is attached to the cradle 3 by the user, the volume level of the analog audio signal A3 is automatically adjusted to the line output level, and the adjusted signal can be transmitted to the cradle 3, without making the user perform the adjusting operation of a volume level.

At this time, the portable disk device 2 switches the volume level of the analog audio signal A3 to a fixed line output level based on the line volume value VL, irrespective of the volume level before attached to the cradle 3 (that is, the headphone volume value VH). Thereby, an analog audio signal A3 at a constant volume level can be transmitted to the cradle 3 at any time.

Responding to this, in the cradle 3, the line output level of the analog audio signal A3 is changed to a volume level corresponding to a speaker volume value VS that was adjusted by the user by the operation of the operation button group 20 (FIG. 1) and has been stored in the storage part 61, and the sound is emitted from the speakers 4L and 4R.

Therefore, only by that the portable disk device 2 is attached, the cradle 3 can represent a volume level based on the speaker volume value VS that was adjusted matching the user's preference for the last time and has been stored in the above cradle 3, and can emit an audio sound from the speakers 4L and 4R, irrespective of the headphone volume value VH stored in the above portable disk device 2. Thus, it is unnecessary to make the user adjust a volume level every time when attaching the above portable disk device 2.

Further, in an attached state that the portable disk device 2 has been attached to the cradle 3, the dedicated headphone connecting terminal 11 is closed by the above cradle 3 (FIG. 1). Thereby, it can be prevented that the dedicated headphones 15 is connected by mistake. Therefore, it can be limited that an analog audio signal A3 at a line output level to be transmitted to the cradle 3 is erroneously transmitted to the output parts 15DL and 15DR of the dedicated headphones 15. It prevents that the user listens to an audio sound at a too large volume level.

On the other hand, if the portable disk device 2 is detached from the cradle 3 (FIG. 2A) by a user, the cradle 3 determines that the potential of a connection detecting line DET (FIG. 4) is “H” level and detects that the above portable disk device 2 is an unattached state, makes the DSP 53 switch the volume level of digital audio data D2 from a volume level based on a line volume value VL to a volume level based on a headphone volume value VH, and transmits an analog audio signal A3 adjusted to a headphone output level from the headphone terminal part 11A of the dedicated headphone connecting terminal 11 to the output parts 15DL and 15DR of the dedicated headphones 15.

Accordingly, only by that the portable disk device 2 is detached from the cradle 3 by the user, the volume level of the analog audio signal A3 is automatically adjusted to a headphone output level, and the adjusted signal can be transmitted to the output parts 15DL and 15DR of the dedicated headphones 15, without making the user perform the adjusting operation of a volume level. It can make the user listen to an audio sound at a volume level based on the headphone volume value VH.

At this time, the portable disk device 2 can switch the analog audio signal A3 to a volume level corresponding to the headphone volume value VH, that is, the headphone output level, irrespective of a volume level when it is emitted from the speakers 4L and 4R in the cradle 3 (that is, the speaker volume value VS).

Further, since the headphone volume value VH is stored in the storage part 51, only by that the portable disk device 2 is detached from the cradle 3, the volume level when it was adjusted by the user for the last time can be represented, and it can make the user listen to an audio sound at a volume level matching the users preference from the output parts 15DL and 15DR of the dedicated headphones 15. Thus, it is unnecessary to make the user adjust a volume level every time when detaching the above portable disk device 2 from the cradle 3.

Moreover, the portable disk device 2 can be realized with a simple structure that the connection detecting line DET for detecting an attached state or a detached state between the above portable disk device 2 and the cradle 3 is connected to the power supply Vcc via the pullup resistance 56. It is almost unnecessary to increase the size and the weight of the portable disk device 2; the portability is not lacked.

According to the above configuration, the portable disk device 2 compares the potential of a connection detecting line DET to a threshold value TH, and detects whether the above portable disk device 2 is in an attached state or a detached state. If it is in the attached state, the portable disk device 2 transmits an analog audio signal A3 adjusted to a line output level based on a line volume value VL to the cradle 3 so as to make the user listen to an audio sound at a volume level of the user's preference suitable for the using condition that has been attached to the above cradle 3 from the speakers 4L and 4R. If it is in the unattached state, the portable disk device 2 transmits an analog audio signal A3 adjusted to a headphone output level based on a headphone volume value VH to the dedicated headphones 15. It can make the user listens to an audio sound at a volume level of the user's preference suitable for the using condition that was detached from the cradle 3 from the output parts 15DL and 15DR of the above dedicated headphones 15.

### (6) OTHER EMBODIMENTS

In the aforementioned embodiment, it has dealt with the case where a volume level is adjusted by the DSP 53 based on the control of the control part 50. However, the present invention is not only limited to this but also a volume level may be adjusted by the DAD 54 and other various circuits.

In the aforementioned embodiment, it has dealt with the case where the portable disk device 2 in an attached state transmits an analog audio signal A3 at a line output level corresponding to a fixed line volume value VL to the cradle 3. However, the present invention is not only limited to this but also for example, a speaker volume value VS is stored in the portable disk device 2, and in the attached state, the analog audio signal A3 at the line output level corresponding to the above speaker volume value VS is transmitted to the cradle 3, so that a volume control may not be performed in the above cradle 3.

Further, in the aforementioned embodiment, it has dealt with the case where in an unattached state, the potential of a connection detecting line DET is approximately same as a power supply Vcc, and in an attached state, it is an approximately ground potential. However, the present invention is not only limited to this but also for example, in the unattached state, the potential of the connection detecting line DET may be set to an arbitrary potential higher than a threshold value TH, and in the attached state, it may be set to an arbitrary potential lower than the threshold value TH.

Further, in the aforementioned embodiment, it has dealt with the case where if the potential of the connection detecting line DET is “H” level, the portable disk device 2 is detected to be in an unattached state, and if it is “L” level, the portable disk device 2 is detected to be in an attached state. However, the present invention is not only limited to this but also for example, the connection detecting line DET is grounded via a predetermined ground resistance, and it is connected to the power supply Vcc on the cradle 3 side or the like, so that if the potential of the connection detecting line DET is “H” level, the portable disk device 2 may be detected to be in an attached state, and if it is “L” level, the portable disk device 2 may be detected to be in an unattached state.

Further, in the aforementioned embodiment, it has dealt with the case where an attached state or an unattached state of the portable disk device 2 to the cradle 3 is detected based on the potential of the connection detecting line DET. However, the present invention is not only limited to this but also an attached state or an unattached state may be detected by other various methods such as using a push-type switch.

Further, in the aforementioned embodiment, it has dealt with the case where since in an attached states the dedicated headphone connecting terminal 11 is closed by the cradle 3, the dedicated headphones 15 are prevented from being connected to the portable disk device 2, and it is limited that an analog audio signal A3 at a line output level is not outputted from the output parts 15DL and 15DR of the dedicated headphones 15. However, the present invention is not only limited to this but also for example, in an attached state, the above dedicated headphone connecting terminal 11 is provided at a position not closed by the cradle 3, and a predetermined switch circuit or the like is used, so that an analog audio signal A3 to the headphone terminal part 11A of the above dedicated headphone connecting terminal 11 may be limited in an attached state.

Further, in the aforementioned embodiment, it has dealt with the case where the present invention is applied to the portable disk device 2 cope with MINI DISC. However, the present invention is not only limited to this but also may be applied to a portable CD (Compact Disc) player, a portable hard disk audio player, a portable radio receiver, and the like, or various electronic equipment that can be attached to a cradle of a cellular phone, a portable computer, and the like that have a function to reproduce music.

Further, in the aforementioned embodiments it has dealt with the case where the portable disk device 2 as electronic equipment is formed by the control part 50, the pullup resistance 56 and the connection detecting line DET that serve as detecting means, and the control part 50 and the DSP 53 that serve as control means. However, the present invention is not only limited to this but also electronic equipment may be formed by detecting means and control means that have other various circuit configurations.

### INDUSTRIAL APPLICABILITY

The present invention is applicable to various electronic equipment that can be attached to a cradle.

1. Electronic equipment being able to be attached to a cradle, comprising:
detecting means for detecting an attached state or an unattached state to said cradle; and
control means for controlling to set, if it is detected that said electronic equipment is in an unattached state to said cradle, an audio sound to be emitted from the above electronic equipment to a predetermined first volume level, and to switch if it is detected that it is in an attached state to said cradle, an audio sound to be emitted from said cradle from said first volume level to a predetermined second volume level larger than the above first volume level.

2. The electronic equipment according to claim 1, wherein
said detecting means detects said unattached state by that the potential of a detecting terminal for detecting an attached state or an unattached state to said cradle is a predetermined threshold value or above, and detects said attached state by that the potential of the above detecting terminal is said threshold value or less, or detects said unattached state by that the potential of said detecting terminal is said threshold value or less, and detects said attached state by that the potential of the above detecting terminal is said threshold value or above.

3. The electronic equipment according to claim 1, wherein:
said electronic equipment includes storage means to store a user volume level that was changed by hand by a user; and
said control means sets if said unattached state is detected, the sound to be emitted from said electronic equipment to said user volume level, and switches if the transition from said attached state to said unattached state is detected, the sound to be emitted from said electronic equipment from said second volume level to said user volume level.

4. The electronic equipment according to claim 1, wherein:
said electronic equipment includes an audio output terminal for outputting said sound; and
in said audio output terminal, when said electronic equipment is attached to said cradle, an audio output from said audio output terminal is limited.

5. The electronic equipment according to claim 1, wherein
said first volume level is a volume level to be emitted through headphones, and said second volume level is a volume level to be emitted through a speaker via said cradle.

6. A method for controlling a volume level of electronic equipment being able to be attached to a cradle, comprising the steps of:
detecting an attached state or an unattached state to said cradle; and
controlling to set, if it is detected that said electronic equipment is in an unattached state to said cradle, an audio sound to be emitted from the above electronic equipment to a predetermined first volume level, and to switch, if it is detected that it is in an attached state to said cradle, an audio sound to be emitted from said cradle from said first volume level to a predetermined second volume level larger than the above first volume level.

7. An electronic equipment system having electronic equipment and a cradle capable of attaching the above electronic equipment, wherein
said electronic equipment includes:
detecting means for detecting an attached state or an unattached state to said cradle, and
control means for controlling to set, if it is detected that said electronic equipment is in the unattached state to said cradle, an audio sound to be emitted from the above electronic equipment to a predetermined first volume level, and to switch, if it is detected that it is in the attached state to said cradle, an audio sound to be emitted from said cradle from said first volume level to a predetermined second volume level larger than the above first volume level.
